(19) United States
(12) Patent Application Publication
(10) Pub. No.: US 2007/0085617 A1
(43) Pub. Date: Apr. 19, 2007

(54) Amplifier arrangement for ultra-wideband applications and method

(76) Inventor: Raffaele Salerno, Tavagnacco (IT)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/545,269

(22) Filed: Oct. 10, 2006

(30) Foreign Application Priority Data
Oct. 10, 2005 (DE) DE102005048409.3

(51) Int. Cl. H03B 5/08

(52) U.S. Cl. 331/167

(57) ABSTRACT

An amplifier arrangement for ultra-wideband, UWB, applications and. a method to amplify a UWB signal are presented. A transistor, whose control input forms an input of the arrangement, is connected to a resonant circuit having a controllable resonator frequency. At the resonator circuit, an output of the arrangement is formed. The resonant circuit includes a frequency determining inductance whose value is controllable. By doing this, it is possible to preselect different frequency bands, while achieving the same gain characteristics in each band.

### REFERENCE TO RELATED APPLICATIONS

This application claims the benefit of the priority date of German application DE 10 2005 048 409.3, filed on Oct. 10, 2005, the contents of which are herein incorporated by reference in their entirety.

### FIELD OF THE INVENTION

The present invention relates to an amplifier arrangement for ultra-wideband applications, a receiver, a radio frequency mixer, a frequency divider and a clock generator with the amplifier arrangement and a method to amplify an ultra-wideband signal.

### BACKGROUND OF THE INVENTION

The ultra-wideband, UWB-standard refers to a system capable of signal transmission over a wider frequency range compared to conventional systems. The frequency spectrum occupied by a UWB-signal, that is the bandwidth of the UWB-signal, is at least 25% of the center frequency. Accordingly, a UWB-signal having, for example, a center frequency of 2 GHz, covers a minimum bandwidth of 500 MHz. The most common technique for generation of a UWB-signal is a transmission of pulses, having pulse durations of less than 1 ns. UWB is also referred to as non-sinusoidal communication technique.

Ultra-wideband systems of the first generation allow for a frequency bandwidth of 3.1 to 5 GHz, which is extended by following generations up to 10.6 GHz as an upper limit. Due to the wide available channel bandwidth, as explained above, the achievable data transmission rates are very high. High frequencies and, at the same time, low transmission power leads to a limitation of application to low distance transmission with a range of typically less than 10 meters.

The frequency spectrum according to UWB-standard is divided into thirteen sub-bands, which again are linked together in groups. Within every band having a bandwidth of 576 MHz, the amplification has a tolerance of less than 1 dB. This is also referred to as gain flatness.

In the document “Fully-Integrated Ultra-Wideband CMOS Low Noise Amplifier”, by Christian Grewing, Martin Friedrich, Giuseppe Li Puma, Christoph Sandner, Stefan van Waasen, Andreas Wiesbauer, Kay Winterberg, ESSCIRC 2004, 30th European Solid-State Circuit Conference, 21-23 Sep. 2004, Leuven, Belgium, a low noise amplifier for UWB is presented. The coverage of the great frequency range of several Gigahertz by, at the same time, small variation of the gain over the frequency range is achieved there by implementing the amplifying transistor not as a single device but as a distributed device. To achieve this, several transistors are connected in parallel. The active transistors are connected to each other by transmission lines which combine the transfer functions such as to achieve the desired frequency behavior. A distributed amplifier of that kind has a relatively large power consumption and requires a large chip area in silicon.

Alternatively, a resonant circuit forming a load could be provided, with which the frequency determining capacitance is switched between predefined discrete values in order to achieve different frequency bands. Such devices are also referred to as capacitive-tuned amplifiers. When assembling such an LC parallel resonant circuit, it becomes evident that with increasing frequency, the amplitude is also increasing.

The gain of such a capacitive-tuned amplifier is calculated according to the formula

$$A = {g}_{m} \cdot 2 π \cdot {f}_{o} \cdot Q \cdot {L}_{load} = \frac{{g}_{m}}{2 π} \frac{Q}{{C}_{load} \cdot {f}_{o}} {( \frac{{f}_{0}}{{f}_{o MAX}} )}^{2}$$

where A represents the gain, gₘ the transconductance, Q the quality factor, fₒ the operating frequency, L_{load} the inductive load, C_{load} the capacitive load, and Fₒₘₐₓ the maximum operating frequency.

As can be seen by the above equation, the gain A depends on the frequency significantly. However, this behavior contradicts the gain flatness desired with UWB applications.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

The present invention is directed to an amplifier arrangement for UWB applications as well as a receiver, a radio frequency mixer, a frequency divider, a clock generator and a method for amplification of a UWB-signal, with which the frequency dependence of the gain is reduced with the same power consumption.

According to one embodiment of the invention, an amplifier arrangement for UWB applications is provided, in which a signal input receives an input signal, wherein the signal input is connected to a control input of a transistor. The load is represented by a resonant circuit with a controllable resonator frequency which is coupled to the transistor. The resonant circuit is configured as an LC-oscillator, in which the value of the effective inductance can be controlled. An amplified signal is provided at a signal output which is connected to the resonant circuit.

The capacitance of the LC-oscillator does not necessarily have to be implemented as a discrete or integrated device. Instead, in one embodiment a parasitic capacitance which is present in the circuit can be employed as a frequency-determining capacitance with the desired applications in the radio frequency range.

In one embodiment, the circuit provides a pre-selection of a certain frequency range in a broadband application, which covers several Gigahertz of frequency range, with a resonant load comprising an oscillator, wherein the frequency-determining inductance is controlled, instead of controlling the frequency determining capacitance. Therefore, an inductive-tuned amplifier is provided.

In contrast to switched capacitances, the use of tunable and/or switchable inductances leads to a relatively constant output load impedance over a very large frequency range. This is also due to the fact that the increase of inductivity at low frequencies leads to a compensation of the small frequency and the small quality factor. The gain A′ in such an exemplary arrangement results in the formula:

$${A}^{′} = {g}_{m} \cdot 2 π \cdot {f}_{o} \cdot Q \cdot {L}_{Last} = \frac{{g}_{m}}{2 π} \frac{Q}{{C}_{Last} \cdot {f}_{o}}$$

When comparing the gain of the capacitive-tuned amplifier with the gain of the inductive-tuned amplifier, it may be noted that with the amplifier arrangement suggested, high gain is achieved over a very wide frequency range with a substantially constant power consumption. As the operating frequency is always smaller than the maximum operating frequency, the gain A′ is greater than the gain A for all frequencies. In addition to this, in one embodiment of the present invention, the gain is not affected when switching the inductance into another frequency range.

As an additional advantage, the number of devices can be reduced because it is possible in one embodiment to implement the capacitor as a parasitic device.

In one embodiment, the at least one switch is connected to the frequency-determining inductance for controlling the value of the frequency determining inductance by switching between a first and a second pre-determined value of inductance.

With application in a single-ended version of the circuit, it can be advantageous in one embodiment to connect the switch in parallel to a first inductor and to connect a further inductor in series to the parallel circuit formed by the first inductor and the switch.

In contrast to the above embodiment, with a symmetric structure of the amplifier according to another embodiment, it can be advantageous to implement the frequency-determining inductivity in a symmetric manner with two pairs of inductors, each one of which comprises two inductor devices which are connected to each other in a tapping node. The two tapping nodes are connected to each other via the switch. With differential signal processing, a virtual ground potential will be practically present at the switch. This has significant advantages to the characteristics of the circuit.

Of course, in another embodiment, further switches can be used with the single-ended circuit as well as with the differential embodiment, the further switches being assigned to further inductors in order to achieve further pre-determined values of inductance of the total structure.

The switch or the switches, respectively, are controlled in one embodiment by a control device, which, at its output side, is connected to the control input of the switch or with the control inputs of the switches, respectively.

It is especially advantageous to feed the control device with a value of the desired frequency range or of a group of frequency ranges at its input side.

In order to provide a fine-tuning of the frequency range in addition to a coarse selection of the frequency range, the frequency-determining capacitance can be configured in another embodiment as a controllable capacitor and/or as a tunable capacitor. The capacitance can be switched in discrete steps and/or can be controlled proportionally to a control signal. This is achieved, for example, by varactor diodes.

In one embodiment, it is desirable to assign the at least one transistor a cascode stage. By doing this, the frequency behavior is further improved.

The amplifier arrangement is switched between a receiving antenna and a signal processing unit, in one embodiment. Alternatively, the amplifier arrangement is switched between a signal processing unit and a transmission antenna.

It is, of course, within the scope of the present invention to use the amplifier arrangement in a radio-frequency mixer, a frequency divider or other functional blocks. The invention is applicable in clock generators, for example, in oscillators having an LC tank and IQ generator with injection locking. In order to achieve a radio-frequency mixer, it can be of advantage, for example, to provide a further signal input for receiving a signal having a mixing frequency, which is also referred to as a local oscillator frequency or carrier frequency. The at least one transistor is connected with further transistors for forming a multiplier core. This multiplier core is loaded with an electric load comprising the resonant circuit having a controllable resonator frequency according to one embodiment of the invention.

Accordingly, in one embodiment, a frequency divider can be configured as a master-slave flip-flop with transistors being connected to each other in order to form such a master-slave flip-flop and to which is connected the electric load which is in the form of the resonant circuit with controllable inductance.

In another embodiment, the present invention can also be applied to a clock generator according to the principle of an injection-locked IQ generator.

With these and other applications, the resonant load having a controllable frequency by controlling the frequency determining inductance results in a substantially constant amplitude over several frequency ranges and a substantially constant current consumption over frequency.

According to one embodiment, for an amplification of a UWB-signal, an input signal is amplified by means of a transistor which is connected to an electric load which is in the form of a resonant circuit. The value of an inductance, which is comprised by the resonant circuit, is controlled as a function of a pre-determined channel and/or frequency range. The oscillator further comprises a capacitance, which is in the form of a discrete or integrated device or in the form of a parasitic capacitance. At a tapping node of the oscillator, an amplified signal is provided.

In one embodiment, the value of the inductance is controlled not in an analog manner, but in discrete steps. Further, in one embodiment the inductance is controlled as a function of a pre-determined channel hopping procedure. For example, with UWB applications, different channels can be selected periodically according to a pre-determined channel hopping pattern. Such a control signal can be fed to the controllable inductance in one embodiment.

In order to provide an additional fine-tuning of the oscillator frequency and/or of the frequency range, for example, it can be of advantage in one embodiment to also provide the capacitance as a controllable device, for example, as a device which is controllable in discrete steps or as a tunable device.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

The invention is subsequently explained in further detail using several embodiments with reference to the drawings.

FIG. 1 illustrates a first exemplary embodiment of a UWB amplifier arrangement according to the invention,

FIG. 2 illustrates a second exemplary embodiment of an amplifier arrangement according to the invention,

FIG. 3 illustrates a third exemplary embodiment of an amplifier arrangement for UWB according to the invention,

FIG. 4 is a graph illustrating the frequency bands according to UWB-standard,

FIG. 5 illustrates a structure of an inductance with a switchable value for application in an amplifier arrangement according to one exemplary embodiment of the invention,

FIG. 6 illustrates a comparison of the frequency dependence of the amplitude for different tuning configurations of parallel resonant circuits, FIG. 7 is a graph illustrating an AC behavior of an amplifier arrangement according to one exemplary embodiment of the invention, FIG. 8 illustrates an exemplary application of a UWB amplifier arrangement in a receiver, FIG. 9 is a schematic diagram illustrating an exemplary radio frequency mixer using an amplifier arrangement, FIG. 10 is a schematic diagram illustrating an exemplary frequency divider using the amplifier arrangement, and FIG. 11 illustrates an example of a clock generator using the amplifier arrangement.

### DETAILED DESCRIPTION OF THE INVENTION

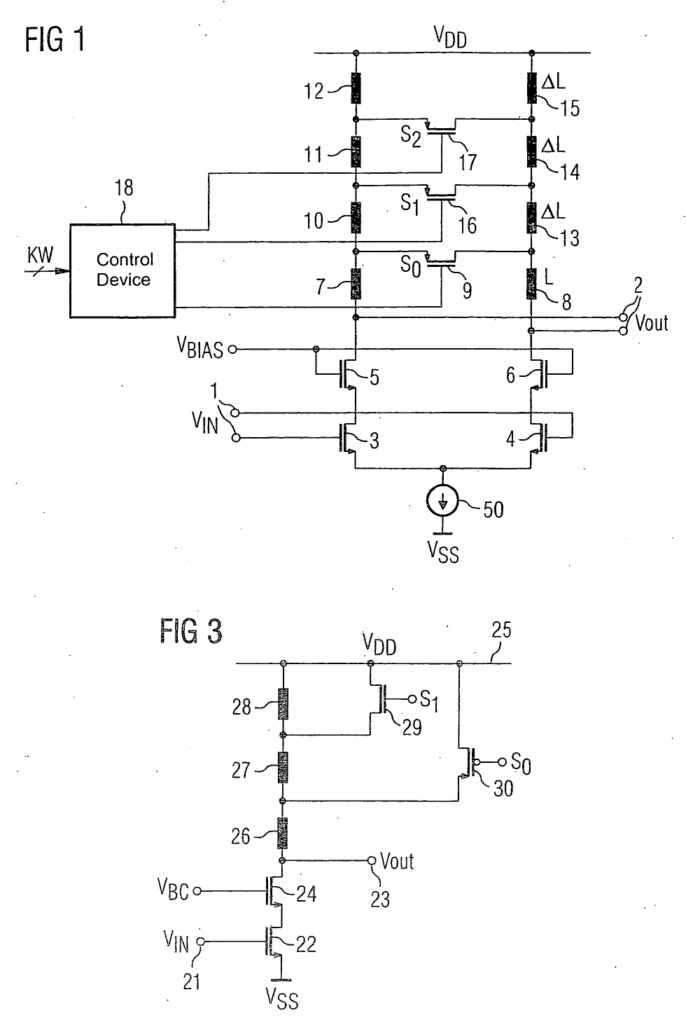

FIG. 1 shows an amplifier arrangement for ultra-wideband applications, UWB. A signal input 1 comprises a pair of terminals for receiving an input signal Vᵢₙ and is designed for differential signal processing. At an output 2, an output signal can be provided, which is referred to as Vₒᵤₜ and represents the amplified input signal. The input terminals 1 are connected to control terminals of. two transistors 3, 4, which form a differential amplifier. For this purpose, the source terminals of these transistors 3, 4 are connected to each other and, via a current source 50, to a ground potential terminal Vₛₛ. On the drain side, each of the transistors 3, 4 is connected to a cascode transistor 5, 6 at its source terminal. The drain terminals of the cascode transistors 5, 6 are connected to the output 2 in symmetric circuit design in this embodiment. The gate terminals of the cascode transistors 5, 6 are configured to receive a constant bias potential V_{bias}. The transistors 3, 4 of the differential amplifier and the assigned cascode transistors 5, 6 are each formed in this exemplary embodiment as an n-channel metal oxide semi-conductor field effect transistor, MOSFET.

Between the symmetric output 2 and a supply potential terminal VDD, an oscillator having a controllable resonator frequency is switched. The oscillator comprises a symmetric inductance 7, 8, 10, 11, 12, 13, 14, 15, whose value is controllable. The frequency determining capacitance of the LC oscillator is not shown as a discrete device, in this embodiment, but is formed by parasitic effects of the radio frequency circuit.

In detail, the frequency determining inductance comprises a pair of inductors such as coils 7, 8, each one of which is, with one terminal, connected to the output 2. A respective further terminal of the coils 7, 8 is connected to each other via a first switch 9. Moreover, the further terminals of the inductive devices 7, 8 are connected, via a series circuit of three inductors 10, 11, 12; 13, 14, 15, respectively, with the supply potential terminal VDD. Tapping nodes between the inductors are connected with a respective further switches 16, 17 to each other, forming a virtual ground. The switches 9, 16, 17 are formed as MOSFETs in one exemplary embodiment. The gate terminals of the switches 9, 16, 17 are connected to outputs of a control device 18. On the input side of the control device 18, a channel word KW can be received, which represents a desired frequency band and/or a desired channel.

Depending on the channel word KW, the switches 9, 16 and 17 are opened and closed, respectively. By doing this, the resonant frequency of the resonator circuit is tuned to the desired frequency of an incoming signal, and its frequency range, respectively.

As explained in more detail below, it is possible, according to the invention, to achieve, independently of the desired frequency range, the same amplitudes for different frequency bands. As a consequence, the frequency dependent function of the gain over different frequency ranges is substantially the same.

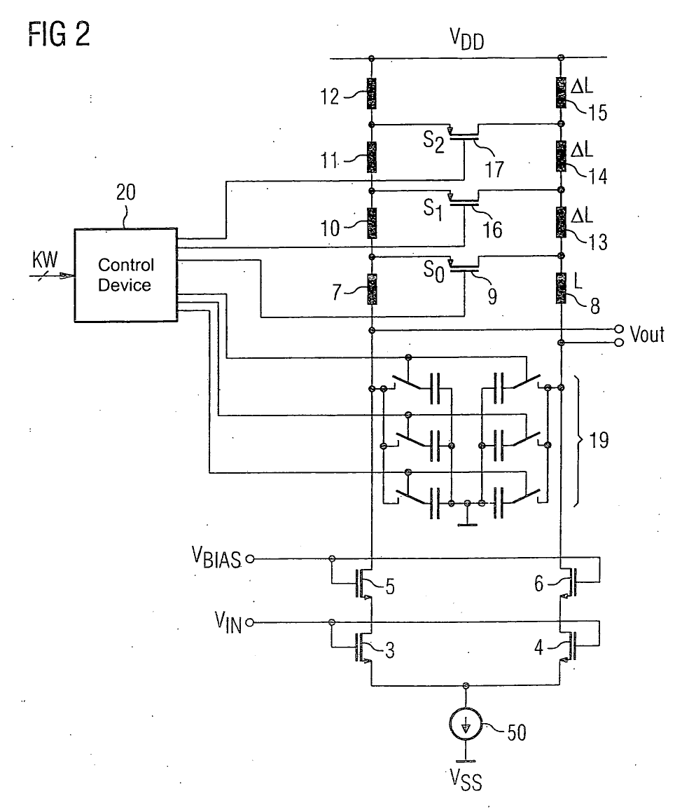

FIG. 2 shows a modification of the circuit of FIG. 1, which is, to a large extent, corresponding to the circuit of FIG. 1 as concerns the devices used, their advantageous connection to each other and their function. As far as this applies, the description is not repeated here. In addition to this, the circuit according to the embodiment of FIG. 2 comprises a capacitor bank 19, which has capacitors which can be connected and disconnected, depending on switch positions, between the terminals of output 2 and therefore, selectively connected or disconnected to the oscillator. To achieve this, in one embodiment, single capacitors are connected in a symmetric architecture via a respective switch in series between the circuit node connected to the output 2 of the circuit and a reference potential terminal. These series circuits are connected to each other in a symmetric circuit design in parallel to each other. The control terminals of the switches are connected, in pairs, to further output terminals of the control device 20.

By means of the additional capacitors 19, it is possible to provide a fine-tuning of the frequency range. The switchable inductors in this exemplary embodiment are used for a coarse tuning of the frequency range.

FIG. 3 shows another modified or alternative embodiment of the circuit of FIG. 1, which is not configured for differential signal processing, but for single-ended signal processing which can be conducted using a single conductor. This amplifier arrangement has a signal input 21, which is connected to the control input of a transistor 22. Between this transistor 22 and an output 23, there is connected a further transistor 24 forming a cascode stage. The output 23 is connected to a supply potential terminal 25 via a series circuit, comprising several inductors 26, 27, 28. A switch 29 is connected in parallel to the conductor 28, which is formed as a transistor. In parallel to the circuit comprising a series configuration of two inductors 27, 28 connected to supply potential, there is connected a further switch 30, which consequently, in an on-state, connects a terminal of the inductor 26 on the output side directly to supply potential. The control circuits of the switches 29, 30 are also connected to a control device which is not shown here and which controls the total inductance in response to a desired frequency range in the form of an input channel word KW. A resonant circuit is formed by the inductors 26 to 28 together with parasitic capacitances in this embodiment.

The function of the circuit of FIG. 3 corresponds to the one of FIG. 1 provided that FIG. 3 refers to a single-ended signal processing instead of a symmetric signal processing.

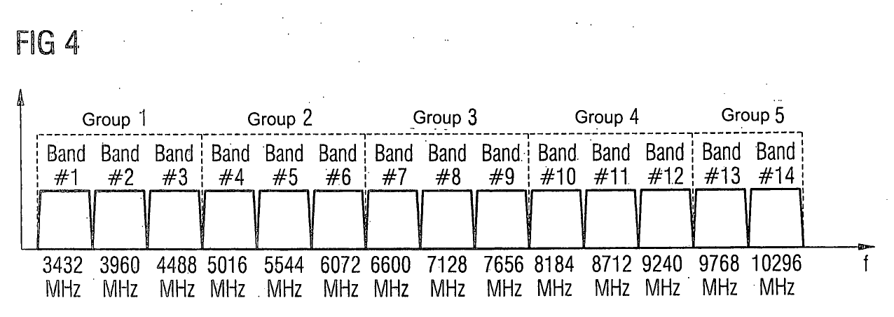

FIG. 4 shows the 14 frequency bands according to the UWB-standard, which cover the frequencies from 3.1 GHz to over 10 GHz. Two to three of these bands are grouped together, respectively. On the frequency axis is in each case shown the center frequency of the associated frequency band.

With respect to the embodiment as shown in FIG. 4, the switchable inductances can provide a selection of the group of frequency bands, while a fine-tuning on a single frequency band and/or a channel can be performed by means of the additional switchable capacitances 19. Of course, it is possible in alternative solutions to omit the capacitive tuning and/or to provide a different assignment of frequency bands to switchable inductances, depending on the application.

Moreover, the present invention is also applicable to other broadband radio applications besides from UWB, and such alternatives are contemplated as falling within the scope of the present invention.

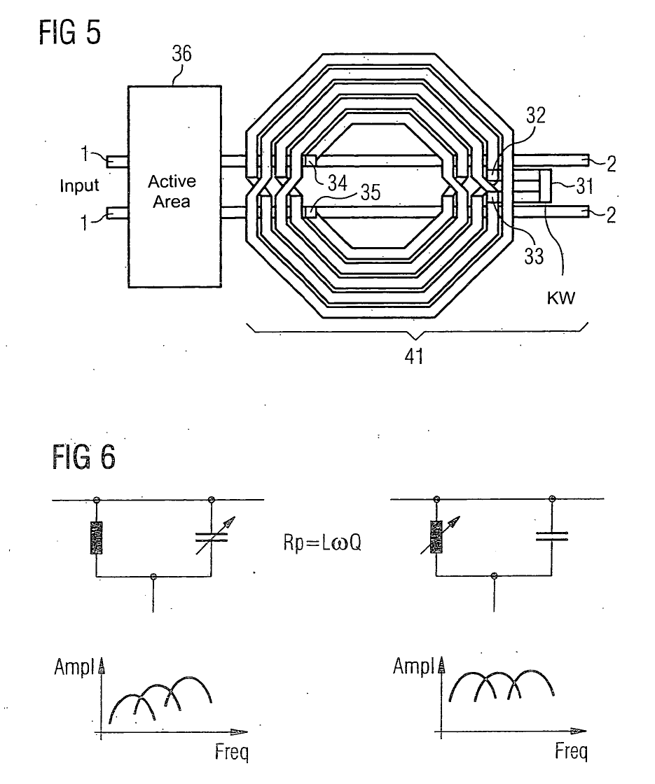

FIG. 5 shows an embodiment of an inductance having a switchable value of inductance by means of switches. A possible layout is shown in a top view. For simplicity, only one switch 31 is shown, which allows for switching between two values of inductance. This switch, in one embodiment, has a gate terminal as a control input. The switch 31 connects two terminals 32, 33 of-the symmetrically designed inductance to each other switchably. The respective other terminal of the inductance 34, 35 is connected to an active area 36, which comprises, for example, the transistors 3, 4, 5, 6 of FIG. 1. In addition to this, the input 1 is formed at the active area. Between the active area 36 and connection pads 34, 35 of the switchable inductor, the output 2 of the circuit is provided, which can be connected at the right side of FIG. 5.

As can be seen, a switchable inductor can be realized in integrated circuit technology with relatively little effort. The inductor in this exemplary embodiment, has good high-frequency properties due to its symmetric spiral layout. It should be mentioned that the area for the switch 31 can be relatively small because the desired quality factor can be relatively small, for example, Q smaller than 8, to achieve the desired gain flatness characteristics.

Therefore, one advantage of an aspect of the invention can be seen in the fact that inductors 7, 8 and 10 to 15 in FIGS. 1 and 2, as well as inductors 26 to 28 in FIG. 3, can be implemented by a single coil having a total inductance, instead of several coils properly connected, thus allowing a compact layout with less parasitic elements.

The coil of the inductive component in accordance with one exemplary embodiment has a plurality of turns and two end contacts. The coil also has an intermediate contact that is electrically coupled to a connection that may be utilized for a voltage supply or for current supply purposes, be grounded, or remain unutilized. The turns of the coil are arranged in one embodiment such that they are essentially transposed with one another, therefore forming partial turns. In this case, the turns are arranged in the same plane, which is referred to as turn plane. In one embodiment, the control circuit of the inductive component has a switch element by means of which it is possible to alter the number of turns between the two tapping contacts of the coil. As a result, it is possible to alter the effective inductance between the tapping contacts 34, 35 in a stepwise manner. The coil can be shorted by means of the switch 31 in such a way that at least one turn of the coil can be connected.

Of course, it is possible in various embodiments of the circuit of FIG. 5 to integrate further switches and to design the spiral inductor to be switchable in additional steps. If a plurality of switch elements are provided in the control circuit, and the switches are electrically coupled to the inductive component via more than two tapping contacts, it is possible to change the effective inductance in a multiplicity of steps. Consequently, a plurality of switch elements results in an inductive component having multiband capability.

In an alternative embodiment, the switch 31 can be formed as a parallel circuit of several switches.

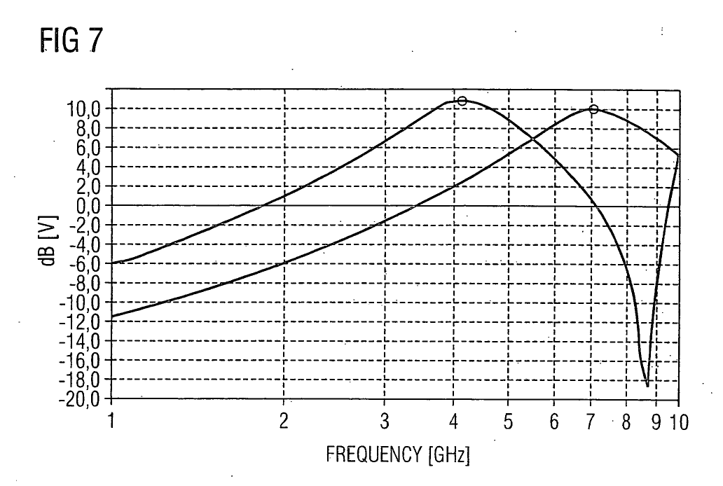

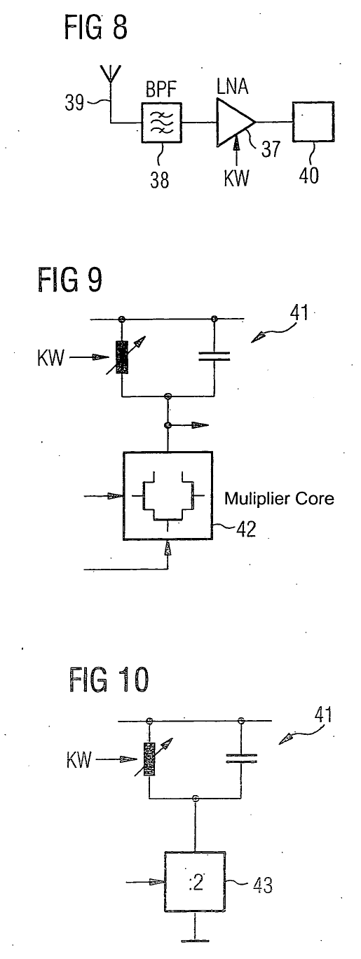

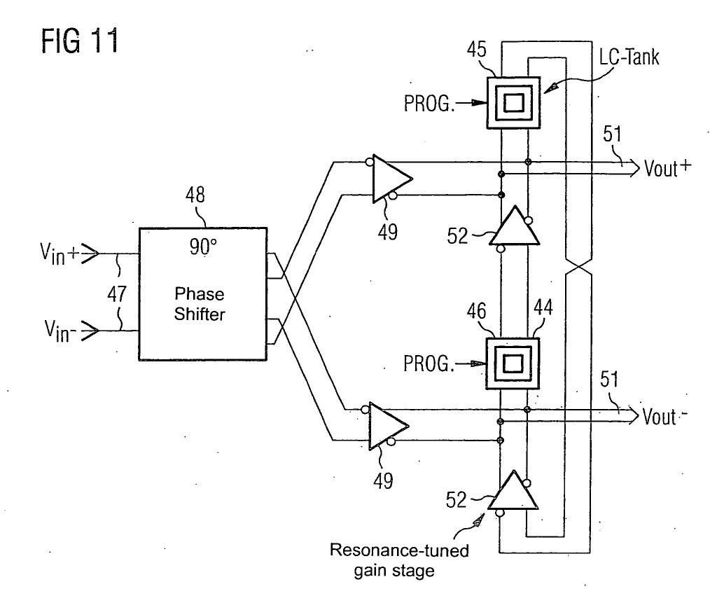

FIG. 6 shows a comparison of two parallel resonant circuits, one of which, shown in the left of FIG. 6, has a controllable capacitance and one has a controllable inductance shown on the right side of FIG. 6. In each case, the lower part of FIG. 6 shows the amplitude over frequency for an amplifier arrangement having such a resonant circuit. As can be seen from FIG. 6, the arrangement presented having controllable inductance allows significantly improved Constance of gain over the frequency, with, at the same time, higher bandwidth, higher gain, and less chip area consumption of the circuit.

FIG. 7 shows the gain in decibel over the frequency in a logarithmic scale. From this AC analysis of an amplifier as suggested it is evident that the circuit as shown in FIG. 5 has the desired properties with respect to gain flatness.

FIG. 8 shows an application example of an amplifier arrangement in accordance with the invention having a switchable resonant frequency. The amplifier arrangement 37 is provided in a receiving path and, on the input side, is connected to an antenna 39 via a bandpass filter 38. On the output side, the amplifier arrangement 37 is connected to a signal processing unit 40. Depending on a frequency range of the input signal, represented by a channel word KW, the inductance of the amplifier 37 is controllable. The amplifier arrangement is formed as a low noise amplifier.

FIG. 9 shows another example of application of an amplifier arrangement according to the invention. A multiplier core 42 is connected to an LC parallel resonant circuit 41, as shown, for example, in FIG. 5, comprising a controllable inductance and a parasitic constant value capacitance. The multiplier core may comprise several transistors, which are connected to each other to perform a multiplication of radio frequency signals, for example, in the manner of a Gilbert multiplier. Depending on a frequency range of an input signal, represented by a channel word KW, the inductance is controlled.

FIG. 10 shows another example application according to the invention. An LC parallel resonant circuit 41 according to one embodiment of the invention is connected to a frequency divider block 43. In this embodiment, the frequency divider block 43 is realized as a master-slave flip-flop to form a divide-by-two frequency divider.

The high-frequency divide-by-two circuit comprises two inductively loaded current-mode flip-flops in a feedback loop clocked for example by a Voltage Controlled Oscillator, VCO, output. Inductive loads are used to tune out the relatively large capacitive load associated with the feedback divider, the buffer stages, and wiring capacitance. The operating frequency range of the injection-locked divider is increased using switchable inductors. In fact, unlike switched capacitors, the use of switchable inductors provides a relatively constant output load impedance across the wide frequency range because the inductance increase at low frequency compensates for the lower frequency and the lower quality factor.

FIG. 11 shows a further exemplary embodiment where the invention is applicable, namely a clock generator. An LC-tank voltage controlled oscillator, VCO, is an application, where both the inductance and the capacitance of the tank are switched in order to increase the frequency tuning range.

A switched inductor can also be used to implement a two-phase, namely inphase and quadrature phase, I and Q, clock frequency integer multiplier. The I-Q clock generator according to FIG. 11 comprises a free-running LC-ring oscillator 44 controlled by an LC tank 45, 46, the frequency being equal to the desired integer multiple of the input frequency. Thus, the output frequency can be changed over a wide range by switching the inductance. Again, unlike switched capacitors, the use of switchable inductors provides a relatively constant output load impedance across the wide frequency range, because the inductance increase at low frequency compensates for the lower frequency and the lower quality factor.

The input signal at the input 47 is 90-degree phase shifted and then injected into the oscillator by means of the phase shifter 48 and injection amplifiers 49, respectively, which are connected downstream. Both the injection amplifiers 49 and the ring oscillator gain cells are differential pairs sharing the same inductive load. Due to its insensitivity to input imbalance, the ring oscillator is able to produce precise quadrature signals at the output 51 when operating above the free-running frequency. Moreover, the generator is capable of tracking the signal variation of the injected source when the input frequency stays within the locking range of the ring oscillator.

The phase noise of the locked generator output is ideally 20*log(N) times higher than the phase noise of the injected source as a result of the frequency multiplication by factor N. The intrinsic phase noise of the LC-oscillator is suppressed when injection-locked, and it does not degrade the signal-to-noise-ratio, SNR of the output local oscillator, LO signals. The injection-locked ring oscillator is also insensitive to input imbalance at its input 47, due to its fully symmetric topology. However, the phase error in the quadrature injected signals should be kept as low as possible, preferably below a predetermined threshold value, so that any phase imbalance that is not filtered by the ring oscillator could be corrected by a phase tuning circuit implemented by varactors for fine tuning which shunt the inductors. The input signal frequency could for example be equal to 5 GHz and the ring oscillator could be tuned to a frequency just below the third harmonic of the injection amplifier outputs, which is 15 GHz.

Although the invention has been illustrated and described with respect to a certain aspect or various aspects, it is obvious that equivalent alterations and modifications will occur to others skilled in the art upon the reading and understanding of this specification and the annexed drawings. In particular regard to the various functions performed by the above described components (e.g., assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.” Also, exemplary is merely intended to mean an example, rather than the best.

1. An amplifier arrangement for ultra-wideband applications, comprising:
a signal input configured to receive an input signal;
a resonant circuit having a controllable resonator frequency comprising at least one frequency determining capacitance and at least one frequency determining inductance, wherein the value of the inductance is controllable;
at least one transistor operably coupled to the resonant circuit and comprising a control input connected to the signal input of the amplifier arrangement; and
a signal output configured to output an amplified signal, the signal output coupled to the resonant circuit.

2. The amplifier arrangement of claim 1, further comprising at least one switch connected to the frequency determining inductance, the at least one switch configured to control its value by switching the inductance between a first and at least a second value of inductance.

3. The amplifier arrangement of claim 2, wherein the inductance comprises a first and second series-connected inductors, and wherein one switch is connected in parallel to the first inductor, and another switch is connected in parallel with the first and second inductors.

4. The amplifier arrangement of claim 2, wherein the frequency determining inductance is formed symmetrically having two pairs of inductors, two of which are in each case connected to each other at a tap node, the tap nodes being selectively to each other via the switch.

5. The amplifier arrangement of claim 1, further comprising a control device configured to receive a channel word, and configured to control the frequency determining inductance as a function of the channel word.

6. The amplifier arrangement of claim 5, wherein the control device is connected at an output thereof to a control input of at least one switch that is configured to selectively alter an inductance of the frequency determining inductance.

7. The amplifier arrangement claim 1, wherein the resonant circuit of the amplifier arrangement is formed symmetrically.

8. The amplifier arrangement of claim 1, wherein the at least one frequency determining capacitance comprises a parasitic capacitance.

9. The amplifier arrangement of claim 1, wherein the at least one transistor comprises an integrated metal isolator semiconductor device.

10. The amplifier arrangement of claim 1, wherein the at least one frequency determining capacitance is controllable, thereby providing a fine tuning of a resonant frequency of the resonant circuit.

11. The amplifier arrangement of claim 1, further comprising a cascode stage coupled between the at least one transistor and the resonant circuit.

12. The amplifier arrangement of claim 1, wherein the at least one inductance comprises a spiral device formed in integrated circuitry, having one or more sets of coupling taps associated therewith, and configured to alter an inductance associated therewith based on a selective shorting of one of the sets of coupling taps.

13. The amplifier arrangement of claim 1 configured in a receiver comprising an antenna and a signal processing unit, wherein the amplifier arrangement is coupled between an antenna and a signal processing unit.

14. The amplifier arrangement claim 1 configured in a radio frequency mixer, the arrangement comprising an additional signal input configured to receive a signal having a mixing frequency, the further signal input connected to a control input of a further transistor, wherein the further transistor and the transistor are connected to each other to form a multiplier core.

15. The amplifier arrangement of claim 1 configured in a frequency divider, wherein the at least one transistor is connected to further transistors to form a flip-flop representing the frequency divider.

16. The amplifier arrangement of claim 1 configured in a clock generator, wherein the amplifier arrangement is arranged in a ring oscillator that is controlled by a phase shifter and an injection amplifier.

17. A method to amplify an ultra-wideband signal, comprising:
amplifying an input signal with a transistor that is connected to a resonant circuit including an electric load;
controlling a value of an inductance of the electric load based on a predetermined channel word, the load of the resonant circuit comprising the inductance and a capacitance;
providing an amplified signal at an output node of the resonant circuit.

18. The method of claim 17, wherein controlling the value of the inductance is performed in discrete steps.

19. The method of claim 18, wherein the inductance is controlled by the channel word that is formulated in response to a predetermined channel hopping procedure.

20. The method of claim 17, further comprising controlling a value of the capacitance for a fine-tuning of the desired frequency range.
